(19) United States
(12) Patent Application Publication
(10) Pub. No.: US 2026/0206251 A1
(43) Pub. Date: Jul. 16, 2026

(54) ENHANCED FIELD EFFECT TRANSISTOR AND FABRICATING METHOD THEREOF

(71) Applicant: SUZHOU INSTITUTE OF NANO-TECH AND NANO-BIONICS (SINANO) , CHINESE ACADEMY OF SCIENCES, Suzhou (CN)

(72) Inventors: Yaozong ZHONG, Suzhou (CN); Qian SUN, Suzhou (CN); Yunzhe CAO, Suzhou (CN); Xin CHEN, Suzhou (CN); Xiaolu GUO, Suzhou (CN); Hongwei GAO, Suzhou (CN); Yu ZHOU, Suzhou (CN); Hui YANG, Suzhou (CN)

(73) Assignee: SUZHOU INSTITUTE OF NANO-TECH AND NANO-BIONICS (SINANO) , CHINESE ACADEMY OF SCIENCES, Suzhou (CN)

(21) Appl. No.: 18/713,674

(22) PCT Filed: Dec. 12, 2023
(86) PCT No.: PCT/CN2023/138193

§ 371 Date: May 27, 2024

(30) Foreign Application Priority Data
Jul. 24, 2023 (CN) 202310912208.X

(51) Int. Cl. H10D 30/47; H10D 62/60; H10D 62/824; H10D 64/27

(52) U.S. Cl. CPC H10D 30/476; H10D 30/475; H10D 62/60; H10D 62/824; H10D 64/513

(57) ABSTRACT

An enhanced field effect transistor and a fabricating method thereof are provided. The enhanced field effect transistor comprises an epitaxial structure, a metal-insulator-semiconductor/metal-oxide-semiconductor (MIS/MOS) gate structure as well as a source electrode and a drain electrode, wherein the epitaxial structure comprises at least one heterojunction in which a carrier channel is formed, a gate region of the epitaxial structure is provided with a gate groove, the groove bottom of the gate groove is located in a first semiconductor layer, a notch is located in a second semiconductor layer, and the carrier channel is separated by the gate groove; the MIS/MOS gate structure comprises a third semiconductor layer, a gate dielectric layer and a gate electrode successively stacked along a selected direction; when a forward voltage is applied to the gate electrode, electrons are reversely generated in the third semiconductor layer, and the carrier channels are electrically connected via the electrons.

### CROSS REFERENCE TO THE RELATED APPLICATIONS

This application is the national phase entry of International Application No. PCT/CN 2023/138193, filed on Dec. 12, 2023, which is based upon and claims priority to Chinese Patent Application No. 202310912208.X, filed on Jul. 24, 2023, the entire contents of which are incorporated herein by reference.

### TECHNICAL FIELD

The present application relates to an enhanced field effect transistor and a fabricating method thereof, in particular to a group III nitride enhanced field effect transistor and a fabricating method thereof, belonging to the technical field of semiconductor electric devices.

### BACKGROUND

Group III nitride semiconductors, known as third-generation semiconductors, have the advantages of large forbidden bandwidth, good chemical stability, high breakdown voltage and the like; moreover, high-electron-mobility transistors (HEMTs) composed of heterojunctions such as AlGaN/GaN have the advantages of high electron concentration and mobility, exhibit excellent performances in the aspects of high frequency, high voltage tolerance, low on resistance and the like, can be used as core devices in various power conversion systems, and have broad prospects in power supply applications of consumer electronics, 5G base stations, servers and the like.

Typically, in actual applications, GaN enhanced HEMT with a threshold voltage of greater than 0 V has natural advantages in the aspects of failure safety and circuit design, and therefore is more suitable for industrial transformation and commercial application. Through some gate technologies, such as a p-GaN gate, a groove gate and an ion injection gate, an energy band of a GaN channel layer can be elevated to deplete a two-dimensional electron gas (2DEG), thereby achieving the purpose of enhancement. In an actual circuit, a gate voltage is in the rapid switching process of high/low voltages, the presence of inductive load may cause a phenomenon of gate voltage oscillation overshoot to occur, and therefore a gate electrode is required to have a relatively high breakdown voltage and threshold voltage. However, high-frequency on-off actions require that the transport of carriers in a gate stack structure has synchronous high-frequency response so that a dynamic threshold voltage drift of a device is small. Hence, an actual application has extremely high requirements on performances and reliability of GaN enhanced HEMT, which is related to the industrialization of GaN HEMT or field effect transistors (FETs). At present, the p-GaN gate enhanced HEMT having technical advantages has achieved industrial transformation and commercial application.

The common gate structures are “metal/p-GaN/AlGaN/GaN” stack structures, as shown in FIG. 1A. In FIGS. 1A, 001 represents a substrate, 002 represents a AlN/AlGaN transition layer, 003 represents a high-resistance (Al)GaN voltage-tolerance layer, 004 represents a (Al)GaN conductive channel layer, 005 represents a AlGaN barrier layer, 006 represents a p type (Al)GaN layer, 007 represents a gate contact metal, 009 represents a source contact metal, and 010 represents a drain contact metal. The deposition of the gate metal layer is mostly performed by adopting processing methods such as evaporation and sputtering, and a work function is in a range of 4-6 eV, such as Ti, Ni and Pb. The epitaxial growth of the p-GaN/AlGaN/GaN stacked layer is mostly performed by adopting metal organic chemical vapor deposition (MOCVD), and the p-GaN layer is in a single-layer structure which is almost uniformly doped with Mg, and has a doping concentration of 1-3×10¹⁹/cm³ and a thickness of 70-150 nm. The AlGaN layer is in a uniform single-layer structure which has 10%-30% of Al component and a thickness of 10-30 nm, and the GaN channel layer is in a single-layer structure which has a thickness of 50-500 nm. It is noted that since the p-GaN/AlGaN/GaN stack structure of p-GaN E-HEMT fabricated by such conventional methods can typically only elevate the conduction band at an AlGaN/GaN interface by Fermi level of no more than 2 V, and therefore a threshold voltage of an actual device is relatively low, with a maximum of only 1-2 V.

As shown in FIG. 1A/B, the gate electrode of the metal/p-GaN/AlGaN/GaN stack can be equivalent to a “Schottky junction” (Jₛ) composed of metal/p-GaN and a “bilateral heterojunction PN junction” (Jₚ) composed of p-GaN/AlGaN/GaN. When the gate electrode forwardly works, the Schottky junction is in a reverse bias state, and bears most of the voltages. Since the effective acceptor concentration of the surface layer p-GaN is typically about 10¹⁹cm⁻³, there is an extremely huge electric field in this Schottky depletion region. The tunneling, acceleration and other behaviors of carriers in the high electric field can cause the original defects in this region to be activated or form new defects, and the significantly increased defect density can lead to failure of this Schottky junction Jₛ. When dynamically turned on, an energy band barrier (typically about 0.2-0.4 eV) between p-GaN/AlGaN blocks the injection of carriers into the GaN channel, and the reversed-biased Schottky junction also blocks the entry of the carriers from the metal into p-GaN. Therefore, the carriers will be depleted or/and accumulated in the depletion region of the metal/p-GaN Schottky junction and the interface of p-GaN/AlGaN, thereby leading to gate dynamic threshold voltage drift (typically, the threshold voltage drift can be up to ±2 V), which brings great instability to gate control.

In conclusion, the gate electrode of the existing group III nitride enhanced HEMT is mostly in a metal/p GaN/AlGaN/GaN stack structure, and the epitaxial growth of p-GaN is performed by using Mg doping and the like to provide holes for acceptors, however, it has at least the following defects:

First, the gate forward breakdown voltage in the above existing technology is low. Due to the extremely high Mg concentration (typically 10¹⁹ cm⁻³ or above) of the acceptor in p-GaN, the self-built electric field strength of the Schottky junction composed of metal/p GaN has been already very high (MV/cm magnitude). Therefore, when a positive voltage is further applied to the p-GaN gate electrode, the Schottky junction composed of metal/p-GaN is reversed-biased and the electric field is further enhanced. Under the strong electric field, extreme carrier transport behaviors such as tunneling and collision ionization are prone to occur, leading to the breakdown of the Schottky junction. The gate breakdown voltage of the conventional p-GaN E-HEMT is usually not higher than 15 V, and the normal working voltage of the gate electrode even does not exceed 6 V. Therefore, this poses a serious challenge to the gate drive of the device.

Second, the threshold voltage in the above existing technology is low. The threshold voltage of p-GaN E-HEMT is mainly determined by the p-GaN/AlGaN/GaN stack structure, and the effective acceptor Mg doping concentration, AlGaN barrier layer, Al component and other factors in p-GaN have important effects on the threshold voltage of the device. Due to the polarization effect between AlGaN/GaN, even though high Mg-doped p-GaN can only elevate the conduction band at the AlGaN/GaN interface by the Fermi level of 1-2 V. Therefore, the traditional p-GaN E-HEMT threshold voltage is usually not higher than 2 V, and the threshold voltage of the actual commercial product is mostly between 1.1 V and 1.5 V. In the actual circuit applications, voltage and current are prone to oscillation due to parasitic effects. The relatively low threshold voltage may cause devices to be mistakenly turned on, resulting in electric energy loss and even circuit damage.

Third, the dynamic threshold voltage drift in the existing technology is large. In the dynamic on-off process, since the transport behavior of gate carriers is affected by the energy band structure and defect states of the p-GaN gate electrode, the gate electrode of the traditional p-GaN E-HEMT will locally generate net positive or negative charge accumulation, resulting in a deviation of the opening voltage of 2DEG in the GaN channel from that in a static state, which is usually manifested as dynamic threshold voltage drift. Due to the low physical performance matching of the Schottky junction and the PN junction constituting p-type gates, the dynamic threshold voltage drift of the traditional p-GaN E-HEMT changes significantly with changes in working voltage, working temperature and other factors. The p-GaN gate enhanced HEMT (p-GaN E-HEMT) gradually moving towards commercial applications still has significant defects in the aspects of gate performance and reliability, restricting its entry into large-scale production and high-end market applications with high reliability requirements, which is extremely unfavorable for device applications in the fields of industrial electronics, automotive electronics and other fields with high stability and reliability requirements.

### SUMMARY

The main objective of the present application is to provide an enhanced field effect transistor having a high gate forward voltage tolerance, a high threshold voltage, a low dynamic threshold voltage drift, and a fabricating method thereof, thereby overcoming the defects in the prior art.

In order to achieve the objective of the previous application, the technical solution adopted by the present application is as follows:

One aspect of the present application provides an enhanced field effect transistor, comprising an epitaxial structure, a metal-insulator-semiconductor/metal-oxide-semiconductor (MIS/MOS) gate structure as well as a source electrode and a drain electrode,
wherein the epitaxial structure comprises at least one heterojunction which comprises a first semiconductor layer and a second semiconductor layer stacked along a selected direction, a carrier channel is formed in an interface between the first semiconductor layer and the second semiconductor layer, and the source electrode and the drain electrode are arranged in an ohmic region of the epitaxial structure and electrically connected with the carrier channel; a gate region of the epitaxial structure is provided with a gate groove, the groove bottom of the gate groove is located in the first semiconductor layer, a notch is located in the second semiconductor layer, and the carrier channel is separated by the gate groove; and
the MIS/MOS gate structure comprises a third semiconductor layer, a gate dielectric layer and a gate electrode successively stacked along the selected direction, the third semiconductor layer is at least arranged in the gate groove, the MIS/MOS gate structure has a field effect on the regulation of the carrier channel, electrons are reversely generated in the third semiconductor layer when a forward voltage is applied to the gate electrode, and the carrier channels located on two sides of the gate electrode are electrically connected via the electrons.

Another aspect of the present application provides a fabricating method of an enhanced field effect transistor, comprising:
providing an epitaxial structure which comprises at least one heterojunction comprising a first semiconductor layer and a second semiconductor layer stacked along the selected direction, carrier channels being formed at an interface between the first semiconductor and the second semiconductor;
removing all the semiconductor layers and a part of the first semiconductor layer located in the gate region of the epitaxial structure, thereby forming a gate groove, the carrier channels being separated by the gate groove;
forming a third semiconductor, a gate dielectric layer and a gate electrode successively stacked at least in the gate region of the epitaxial structure, thus forming an MIS/MOS gate structure, the MIS/MOS gate structure having a field effect on the regulation of the carrier channel, electrons being reversely generated in the third semiconductor layer when a forward voltage is applied to the gate electrode, and the carrier channels located at two sides of the gate groove being electrically connected via the electrons; and
forming a source electrode and a drain electrode in the ohmic region of the epitaxial structure, the source electrode and the drain region being electrically connected with the carrier channel.

Compared with the prior art, the present application has the advantages:
1) the group III nitride enhanced FET provided by the present application has a higher gate forward breakdown voltage;
2) the group III nitride enhanced FET provided by the present application has a higher threshold voltage, and can meet requirements of more application scenarios on the threshold voltages of power electronic devices;
3) the group III nitride enhanced FET provided by the present application has smaller dynamic threshold voltage drift, and the device has better stability.

### BRIEF DESCRIPTION OF THE DRAWINGS

FIG. 1A is a structural diagram of a conventional enhanced HEMT;

FIG. 1B is a structural diagram of an energy band of a conventional enhanced HEMT;

FIG. 2 is a structural diagram of a depleted HEMT epitaxial structure provided in a typical embodiment of the present application;

FIG. 3 is a structural diagram of an HEMT epitaxial structure of a gate groove formed after a gate region is removed in a typical embodiment of the present application;

FIG. 4 is a structural diagram after secondary epitaxy of a p-type semiconductor layer or a unintentional Mg-doped semiconductor on the surface of an HEMT epitaxial structure in a typical embodiment of the present application;

FIG. 5 is a structural diagram of an FET after a gate dielectric layer is deposited in a typical embodiment of the present application;

FIG. 6 is a structural diagram of an FET after a source electrode/drain electrode is fabricated in a typical embodiment of the present application;

FIG. 7 is a structural diagram of an enhanced field effect transistor provided in a typical embodiment of the present application;

FIG. 8 is a structural diagram of another enhanced field effect transistor provided in a typical embodiment of the present application;

FIG. 9 is a structural diagram of another enhanced field effect transistor provided in a typical embodiment of the present application;

FIG. 10 is a structural diagram of another enhanced field effect transistor provided in a typical embodiment of the present application;

FIG. 11 is a structural diagram of energy bands of another enhanced field effect transistor under different gate voltages provided in a typical embodiment of the present application;

FIG. 12 is a static and dynamic transfer characteristic curve graph of another enhanced field effect transistor provided in a typical embodiment of the present application.

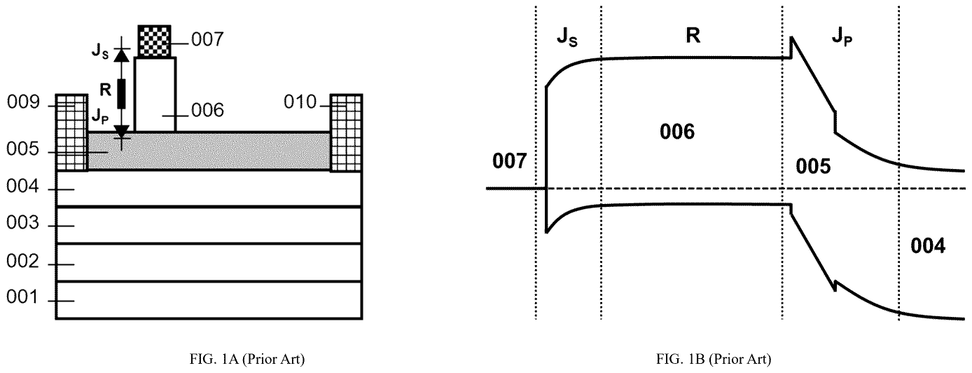

### DETAILED DESCRIPTION OF THE EMBODIMENTS

In view of the defects in the prior art, the inventor of this case proposes the technical solution of the present application via long-term researches and a lot of practices. Next, the technical solution, implementation process and principle of the present application will be further explained and described.

One aspect of the present application provides an enhanced field effect transistor, comprising an epitaxial structure, an MIS/MOS gate structure as well as a source electrode and a drain electrode,
wherein the epitaxial structure comprises at least one heterojunction comprising a first semiconductor layer and a second semiconductor layer stacked along the selected direction, a carrier channel is formed in an interface between the first semiconductor layer and the second semiconductor layer, and the source electrode and the drain electrode are arranged in an ohmic region of the epitaxial structure and electrically connected with the carrier channel; the gate region of the epitaxial structure is provided with a gate groove, the groove bottom of the gate groove is located in the first semiconductor layer, a notch is located in the second semiconductor layer, and the carrier channel is separated by the gate groove; and
the MIS/MOS gate structure comprises a third semiconductor layer, a gate dielectric layer and a gate electrode successively stacked along the selected direction, the third semiconductor layer is at least arranged in the gate groove, the MIS/MOS gate structure has a field effect on the regulation of the carrier channel, electrons are reversely generated in the third semiconductor layer when a forward voltage is applied to the gate electrode, and the carrier channels located on two sides of the gate electrode are electrically connected via the electrons.

It is noted that under zero bias, the type of the carriers in the semiconductor channel below the gate electrode is opposite to that in the non-gate region.

Further, the third semiconductor layer comprises at least one p-type semiconductor layer and/or at least one unintentionally doped semiconductor layer with acceptor or acceptor-like defects.

Further, the materials of two or more p-type semiconductor layers or two or more unintentionally doped semiconductor layers with acceptor or acceptor-like defects, which are included in the third semiconductor layer, are different.

It is noted that two layers of p-type semiconductors arranged can be in a p-type AlGaN/GaN bilayer structure; when the p-type semiconductor is reversed, the formed electrons can be limited in a potential well formed by AlGaN/GaN, thus improving the mobility and reducing the resistance of the gate region; the effect of the arrangement of two or more unintentionally doped semiconductor layers with acceptor or acceptor-like defects is basically the same as that of the arrangement of two p-type semiconductor layers.

Further, the p-type semiconductor layer is Mg-doped, and the Mg doping concentration of the p-type semiconductor layer is less than 1×10²⁰ cm⁻³.

Further, the Mg doping concentration of the p-type semiconductor layer is 1×10¹⁵ cm⁻³-1×10²⁰ cm⁻³, preferably 5×10¹⁷ cm⁻³-1×10¹⁹ cm⁻³.

Further, the Mg element in the p-type semiconductor layer is uniformly, linearly or gradually distributed.

Further, the material of the p-type semiconductor layer comprises a p-type group III nitride.

Further, the material of the p-type semiconductor layer comprises p-GaN, p-AlGaN, p-AlInGaN, p-InGaN, p-AlInN or p-(Al,In)GaN, but is not limited thereto.

Further, the concentration of the acceptor or acceptor-like defects of the unintentionally doped semiconductor layer is 1×10¹⁵ cm⁻³ or above, and the unintentionally doped semiconductor layer is in a high-resistivity state.

Further, the material of the unintentionally doped semiconductor layer comprises an unintentionally Mg-doped group III nitride.

Further, the material of the unintentionally doped semiconductor layer comprises unintentionally Mg-doped GaN, AlGaN, AlInGaN, InGaN, AlInN or (Al,In)GaN, but is not limited thereto.

It is noted that the unintentionally Mg-doped group III nitride in the third semiconductor layer mainly differs from the unintentionally doped group III nitride as a channel layer in that the unintentionally Mg-doped group III nitride has acceptor or acceptor defects, and is in a high-resistivity state, however, the unintentionally doped group III nitride as the channel layer is typically in weak n type.

Further, the third semiconductor layer is arranged in the gate region of the epitaxial structure, or, the third semiconductor layer is arranged in the gate region of the epitaxial structure and a region between the gate region and the ohmic region.

Further, the gate dielectric layer is arranged in the gate region of the epitaxial structure and the region between the gate region and the ohmic region.

Further, the material of the gate dielectric layer comprises Al₂O₃, HfO₂, Si₃N₄ or SiO₂, but is not limited thereto.

Further, the thickness of the gate dielectric layer is 5-100 nm.

Further, the epitaxial structure comprises two or more of the heterojunctions stacked along the selected direction, and the groove bottom of the gate groove is located in the first semiconductor layer of the heterojunction at the bottom.

Further, the materials of the first semiconductor layer and the second semiconductor layer both comprise group III nitrides.

Further, the materials of the first semiconductor layer and the second semiconductor layer comprise GaN, AlGaN, AlInGaN, InGaN, AlInN or (Al,In)GaN, but are not limited thereto.

Further, the epitaxial structure also comprises a high-resistance voltage-tolerance layer and a transition layer, the heterojunction is arranged on the high-resistance voltage-tolerance layer along the selected direction, and the high-resistance voltage-tolerance layer is arranged on the transition layer.

Further, the materials of the high-resistance voltage-tolerance layer and the transition layer both comprise group III nitrides.

Another aspect of the present application also provides a fabricating method of an enhanced field effect transistor, comprising:
providing an epitaxial structure which comprises at least one heterojunction comprising a first semiconductor layer and a second semiconductor layer stacked along the selected direction, and a carrier channel being formed at an interface between the first semiconductor and the second semiconductor;
removing all the semiconductor layer and a part of the first semiconductor layer located in the gate region of the epitaxial structure, thereby forming a gate groove, the carrier channel being separated by the gate groove;
forming a third semiconductor, a gate dielectric layer and a gate electrode successively stacked at least in the gate region of the epitaxial structure, thereby forming an MIS/MOS gate structure, the MIS/MOS gate structure having a field effect on the regulation of the carrier channel, electrons being reversely generated in the third semiconductor layer when a forward voltage is applied to the gate electrode, and the carrier channels located at two sides of the gate groove being electrically connected via the electrons; and
forming a source electrode and a drain electrode in the ohmic region of the epitaxial structure, the source electrode and the drain region being electrically connected with the carrier channel.

Further, the third semiconductor layer comprises at least one p-type semiconductor layer and/or at least one unintentionally doped semiconductor layer with acceptor or acceptor-like defects.

Further, the materials of two or more p-type semiconductor layers or two or more unintentionally doped semiconductor layers with acceptor or acceptor-like defects, which are included in the third semiconductor layer, are different.

Further, the p-type semiconductor layer is Mg-doped, and the Mg doping concentration of the p-type semiconductor layer is less than 1×10²⁰ cm⁻³.

Further, preferably, the Mg doping concentration of the p-type semiconductor layer is 1×10¹⁵ cm⁻³-1×10²⁰ cm⁻³, preferably 5×10¹⁷ cm⁻³-1×10¹⁹ cm⁻³.

Further, the material of the p-type semiconductor layer comprises a p-type group III nitride. Further, the material of the p-type semiconductor layer comprises p-GaN, p-AlGaN, p-AlInGaN, p-InGaN, p-AlInN or p-(Al,In)GaN, but is not limited thereto.

Further, the concentration of the acceptor or acceptor-like defects of the unintentionally doped semiconductor layer is 1×10¹⁵ cm⁻³ or above, and the unintentionally doped semiconductor layer is in a high-resistivity state.

Further, the concentration of the acceptor or acceptor-like defects of the unintentionally doped semiconductor layer is 1×10¹⁵ cm⁻³-1×10²⁰ cm⁻³, preferably 5×10¹⁷ cm⁻³-1×10¹⁹ cm⁻³.

Further, the material of the unintentionally doped semiconductor layer comprises an unintentionally Mg-doped group III nitride.

Further, the material of the unintentionally doped semiconductor layer comprises unintentionally Mg-doped GaN, AlGaN, AlInGaN, InGaN, AllInN or (Al,In)GaN, but is not limited thereto.

Further, the third semiconductor layer is arranged in the gate region of the epitaxial structure, or, the third semiconductor layer is arranged in the gate region of the epitaxial structure and a region between the gate region and the ohmic region.

Further, the gate dielectric layer is arranged in the gate region of the epitaxial structure and the region between the gate region and the ohmic region.

Further, the material of the gate dielectric layer comprises Al₂O₃, HfO₂, Si₃N₄ or SiO₂, but is not limited thereto.

Further, the thickness of the gate dielectric layer is 5-100 nm.

Further, the epitaxial structure comprises two or more of the heterojunctions stacked along the selected direction, and the groove bottom of the gate groove is located in the first semiconductor layer of the heterojunction at the bottom.

Further, the materials of the first semiconductor layer and the second semiconductor layer both comprise group III nitrides.

Further, the materials of the first semiconductor layer and the second semiconductor layer comprise GaN, AlGaN, AlInGaN, InGaN, AlInN or (Al,In)GaN, but are not limited thereto.

Next, further explanations and descriptions of the technical solution, implementation process, and principle will be further explained in conjunction with accompanying drawings and specific embodiments. Unless otherwise specified, a semiconductor epitaxial growth process and equipment thereof, photolithography and etching processes and equipment thereof, a surface repair process, annealing process and equipment thereof, a metal deposition process and equipment thereof, I-V testing equipment, and various reagents used in embodiments of the present application are all known to those skilled in the art, and specific process parameters and process equipment models are not limited herein.

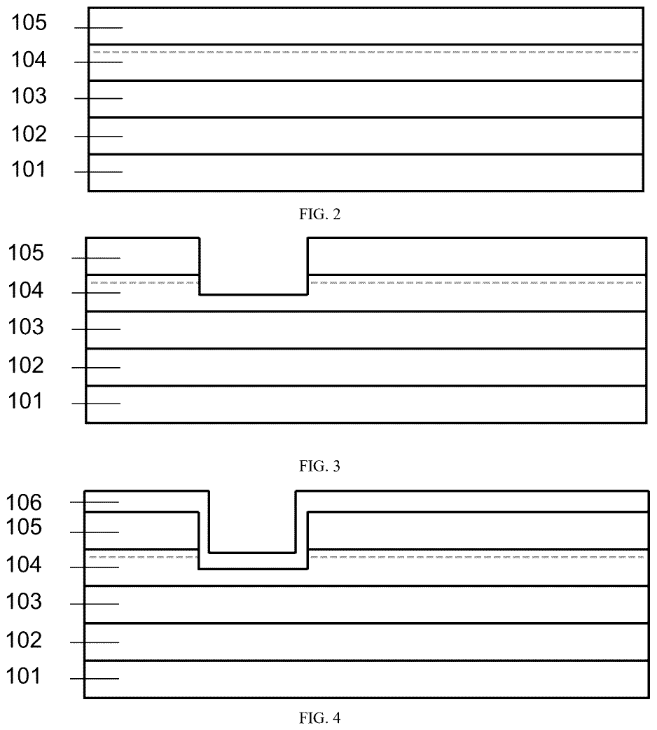

Referring to FIG. 2-FIG. 7, in some specific embodiments, a fabricating method of a group III nitride enhanced field effect transistor (FET) can comprise the following steps:
1) A transition layer 102, a high-resistance voltage-tolerance layer 103, a channel layer (i.e., the previous first semiconductor layer, the same below) 104 and a barrier layer (i.e., the previous second semiconductor layer, the same below) 105 stacked are successively formed on a substrate 101 to form a depleted HEMT epitaxial wafer, as shown in FIG. 2.

Specifically, the transition layer 102 can be a AlN/AlGaN transition layer, the high-resistance voltage-tolerance layer 103 can be a high-resistance (Al)GaN voltage-tolerance layer, the channel layer 104 can be a (Al)GaN conductive channel layer, and the barrier layer 105 can be a AlGaN barrier layer.
2) The gate region of the depleted HEMT epitaxial wafer is photoetched for patterning, and then the barrier layer 105 of the gate region and a part of channel layer 104 are removed by using methods such as dry etching to form a gate groove, as shown in FIG. 3.
3) The surface of the etched depleted HEMT epitaxial wafer is treated to a certain extent (such as wet etching, thermal treatment and decomposition), and subsequently the secondary epitaxy of a p-type semiconductor layer or an unintentionally Mg-doped semiconductor layer 106 is carried out on the surface of the depleted HEMT epitaxial wafer, as shown in FIG. 4.

Specifically, the thickness of the p-type semiconductor or the unintentionally Mg-doped semiconductor layer 106 with acceptor or acceptor-like defects is 15-16 nm.

Specifically, the p-type semiconductor layer is Mg-doped, and the Mg doping concentration of the p-type semiconductor layer is less than 1×10²⁰ cm⁻³, preferably, the Mg doping concentration of the p-type semiconductor layer is 1×10¹⁵ cm⁻³-1×10²⁰ cm⁻³, preferably 5×10¹⁷ cm⁻³-1×10¹⁹ cm⁻³, for example, the Mg doping concentration of the p-type semiconductor layer is 1×10¹⁵ cm⁻³-1×10²⁰ cm⁻³, preferably 5×10¹⁷ cm⁻³-1×10¹⁹ cm⁻³; preferably, the Mg element in the p-type semiconductor layer is gradually increased from 5×10¹⁷ cm⁻³ to 5×10¹⁷ cm⁻³ along a direction deviating from the barrier layer 105, and the material of the p-type semiconductor layer comprises p-GaN, p-AlGaN, p-AlInGaN, p-InGaN, p-AlInN or p-(Al,In)GaN, and the like.

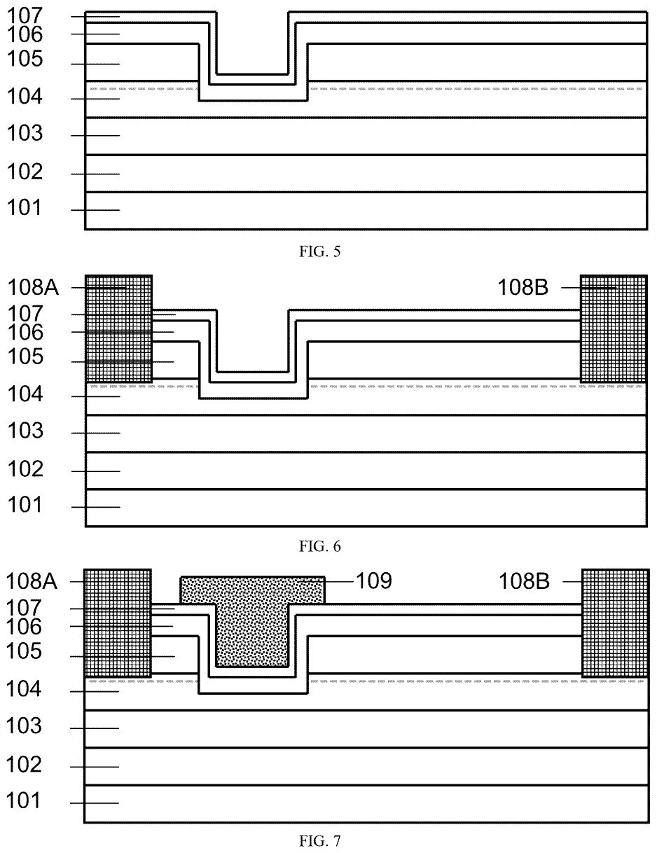

Specifically, the concentration of the acceptor or acceptor-like defects of the unintentionally doped semiconductor layer is 1×10¹⁵ cm⁻³ or above, the unintentionally doped semiconductor layer is in a high-resistivity state; preferably, the concentration of the acceptor or acceptor-like defects of the unintentionally doped semiconductor layer is 1×10¹⁵ cm⁻³-1×10²⁰ cm⁻³, preferably 5×10¹⁷ cm⁻³-1×10¹⁹ cm⁻³; further, the unintentionally Mg-doped semiconductor layer with acceptor or acceptor-like defects is in a high-resistivity state, and the material of the unintentionally Mg-doped semiconductor layer with acceptor or acceptor-like defects comprises unintentionally Mg-doped GaN, AlGaN, AlInGaN, InGaN, AlInN or (Al,In)GaN, and the like.
4) A gate dielectric layer 107 is deposited on the p-type semiconductor layer or the unintentionally Mg-doped semiconductor layer 106 with acceptor or acceptor-like defects, as shown in FIG. 5.

Specifically, the thickness of the gate dielectric layer 107 is 5-100 nm, and the material of the gate dielectric layer 107 comprises Al₂O₃, HfO₂, Si₃N₄ or SiO₂, or the like.
5) A source region and a drain region are etched and the channel layer 104 is exposed, stack metals are respectively deposited on the source region and the drain region, and then the stack metals are annealed to form a source electrode 108A and a drain electrode 108B, as shown in FIG. 6.
6) Gate metals are deposited on the gate dielectric layer 107 located in the gate region to form a gate electrode 109, and a MOS gate structure is formed by using the p-type semiconductor layer or unintentionally Mg-doped semiconductor layer 106, the gate dielectric layer 107 and the gate electrode 109, thereby obtaining the MOS gate FET, as shown in FIG. 7.

It is noted that the above solution can also include more subsequent device processing processes, such as deposition of interconnected metals and preparation of field board structures. In addition, the fabricating order of the source electrode 108A/drain electrode 108B and the gate electrode 109 can be changed according to the actual process, even moves to other procedures.

Specifically, in other specific embodiments, the secondary epitaxy of a first p-type semiconductor layer or unintentionally Mg-doped semiconductor layer 106A, a second p-type semiconductor layer or unintentionally Mg-doped semiconductor layer 106B can also be carried out in step 4, thereby forming the p-type semiconductor layer or unintentionally Mg-doped semiconductor layer. The material of the first p-type semiconductor layer or unintentionally Mg-doped semiconductor layer 106A is different from that of the second p-type semiconductor layer or unintentionally Mg-doped semiconductor layer 106B, the thickness of the first p-type semiconductor layer or unintentionally Mg-doped semiconductor layer 106A is about 10 nm, and the thickness of the second p-type semiconductor layer or unintentionally Mg-doped semiconductor layer 106B is about 5 nm. In this solution, the first p-type semiconductor layer or unintentionally Mg-doped semiconductor layer 106B, the second p-type semiconductor layer or unintentionally Mg-doped semiconductor layer 106B, the gate dielectric layer 107 and the gate electrode 109 form the MIS gate structure, and the finally obtained MIS gate FET is as shown in FIG. 8.

Specifically, in other some specific embodiments, in step 4), the p-type semiconductor layer or unintentionally Mg-doped semiconductor layer 106 is only formed in the gate region, or, the p-type semiconductor layer or unintentionally Mg-doped semiconductor layer 106 in a non-gate region is removed through etching after the p-type semiconductor layer or unintentionally Mg-doped semiconductor layer 106 is formed, and the structure of the finally formed group III nitride enhanced FET is as shown in FIG. 9.

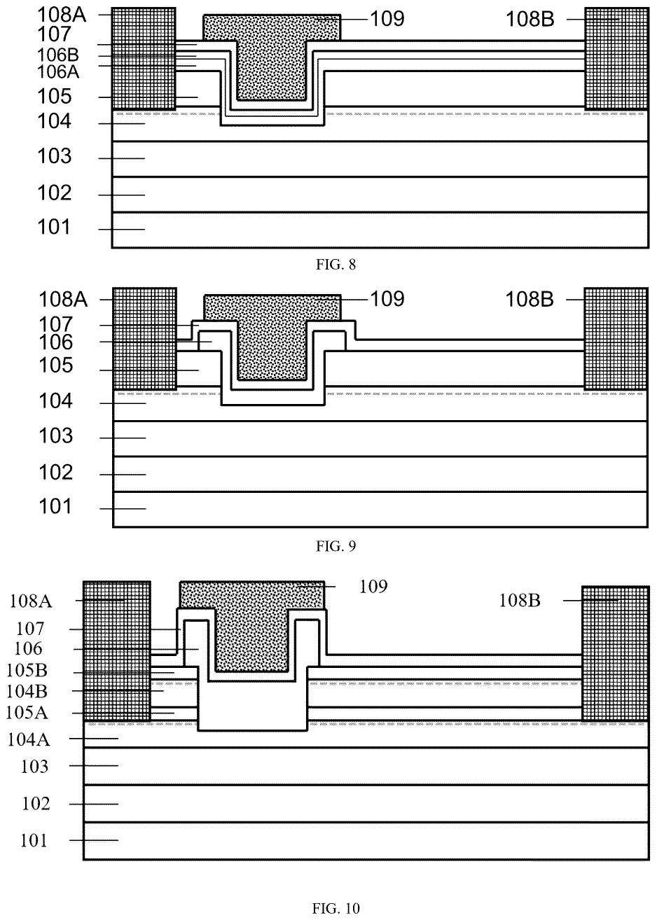

Specifically, in other some specific embodiments, in step 1), the transition layer 102, the high-resistance voltage-tolerance layer 103, the first channel layer 104A, the first barrier layer 105A, the second barrier layer 104B, the second barrier layer 105B stacked are successively formed on the substrate 101 to form the depleted HEMT epitaxial wafer, correspondingly, the groove bottom of the gate groove of the formed gate electrode is located in the first channel layer 104A; the structure of the finally formed group III nitride enhanced FET is as shown in FIG. 10.

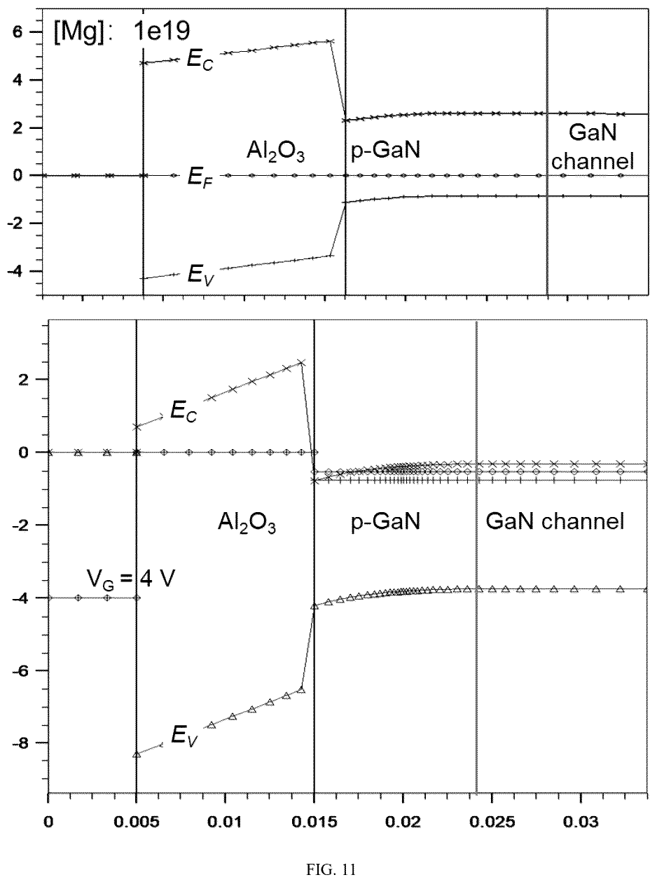

The energy band structures of this first group III nitride enhanced FET at different gate voltages are as shown in FIG. 11.

The present application provides a group III nitride enhanced FET which has a higher gate forward breakdown voltage. There is an electrically insulated gate dielectric layer (preferably, 5-100 nm) between the gate metal of a novel GaN enhanced FET provided by the present application and the p-type semiconductor layer or unintentionally Mg-doped semiconductor layer. Such the electrically insulated gate dielectric layer mostly adopts Al₂O₃, HfO₂ and the like formed by atomic layer deposition or Si₃N₄ or SiO₂ formed by low pressure chemical vapor deposition (LPCVD), these deposited gate dielectric layers have extremely high quality and strong breakdown electric fields and therefore can bear extremely high working voltages (20 V or above); therefore the MIS/MOS gate electrode structures fabricated by using the dielectric layers have high breakdown voltages.

The present application provides a group III nitride enhanced FET which has a higher threshold voltage. In the novel MIS/MOS gate electrode structure provided by the present application, the Fermi level of p-GaN is typically within 1.0 eV above the valence band, even pinned to the position of Mg impurity (EV+ about 0.15 eV), however, the forbidden banwidth of GaN reaches 3.4 eV, so the voltage required to force p-GaN to undergo inversion is relatively high (usually 2.5 V or above), and therefore the threshold voltage can reach 2.4-3.3 V, meeting the threshold voltage requirements for power electronic devices in multiple application scenarios.

The present application provides a group III nitride enhanced FET which has smaller dynamic threshold voltage drift. Since the inversion electrons in p-GaN are generated by field effect induction, there is no problem that the concentration of 2DEG in the channel below the traditional p-GaN E-HEMT gate electrode and the like are severely affected by gate carrier transport behaviors. In addition, since the inversion electrons are minority carriers in p-GaN, they are extremely short (ps grade) in service life, and therefore a net charge accumulation effect is also difficult to occur. Thus, in the rapid on-off process, the inversion electrons in the p-GaN channel of the gate region can rapidly response and generate small threshold voltage drift, and the device has better stability.

When the unintentionally doped semiconductor layer with acceptor or acceptor-like defects is alone used as the third semiconductor layer, the mechanism and effect of the unintentionally doped semiconductor layer with acceptor or acceptor-like defects is basically the same as that when the p-type semiconductor layer is alone used as the third semiconductor layer.

### Example 1

A fabricating method of a group III nitride enhanced FET comprised the following steps:
1) A depleted HEMT (D-HEMT) epitaxial wafer was grown on a substrate.

Specifically, a 600 nm AlN/AlGaN transition layer, a 4 μm C-doped Al_{0.07}Ga_{0.93}N high-resistance layer, an 300 nm high-quality low-electron-concentration unintentionally doped semiconductor layer and a 40 nm Al_{0.20}Ga_{0.80}N barrier layer were successively deposited on a Si<111> substrate by using an MOCVD method and the like to form the depleted HEMT epitaxial wafer of a AlGaN/GaN heterojunction with a two-dimensional electronic gas square resistance of 350Ω/□, a concentration of about 1.0×10¹³ cm⁻³ and a mobility of about 1800 cm²V⁻¹s⁻¹.
2) A gate groove was processed in a gate region of the depleted HEMT epitaxial wafer.

Specifically, the gate region of the depleted HEMT epitaxial wafer was patterned by using photoresist as a mask, and placed in inductively coupled plasma (ICP) etching equipment to etch off all the Al_{0.20}Ga_{0.80}N barrier layer and the about 8 nm unintentionally doped GaN layer of the gate region at a low speed, so as to form the gate groove;
the photoresist was removed by using an organic washing method such as acetone, and the depth of the gate groove was measured as 47-48 nm via test;
after residual organic matters were removed by using a piranha solution, the depleted HEMT epitaxial wafer with the grate groove was placed in tetramethylammonium hydroxide to be heated for a certain time, then transferred to a hydrofluoric acid buffered oxide etchant (BOE) to be soaked so as to remove surface oxides and surface silicon impurities.
3) An MOS gate structure, a source electrode and a drain electrode were fabricated on the depleted HEMT epitaxial wafer.

Specifically, the treated depleted HEMT epitaxial wafer was re-loaded into the MOCVD equipment and heated to 900° C. along with the temperature of a furnace, the temperature was maintained for a while, then a Ga source, NH₃, N₂, Cp₂Mg and the like were introduced into the furnace, so as to perform epitaxial growth on the surface of the depleted HEMT epitaxial wafer to form a p-GaN layer, the thickness of the p-GaN layer was 15-16 nm, the concentration of Mg was gradually increased from 5×10¹⁷ cm⁻³ to 1×10¹⁹ cm⁻³ along a direction deviating from the depleted HEMT epitaxial wafer;

After epitaxy was performed on the p-GaN layer, the atmosphere in the MOCVD furnace was switched to N₂, the temperature of the MOCVD furnace was adjusted to 800° C., and then maintained for a while, followed by cooling to room temperature;

The depleted HEMT epitaxial wafer was taken and placed in atom layer deposition (ALD) equipment for deposition to form a 20 nm Al₂O₃ layer on the p-GaN layer;

Then, the source region and the drain region (i.e., an ohmic region) were photoetched and patterned, the Al₂O₃ layer, the p-GaN layer and the Al_{0.20}Ga_{0.80}N barrier layer which were located in the source region and the drain region were etched off in the ICP equipment, and a layer of Ti/Al/Ti/Au=20/130/50/150 nm stack metal was deposited in the source region and the drain region, followed by rapidly annealing for 30 s at the atmosphere of N₂ and at the temperature of 890° C. to fabricate the source electrode and the drain electrode which were in ohmic contact;
a layer of Ti/Au=20/200 nm stack metal was deposited in the gate region followed by rapidly annealing for 60 s at the atmosphere of N₂ and at the temperature of 500° C. to form an MOS gate structure, thereby obtaining the MOS gate FET, as shown in FIG. 7.

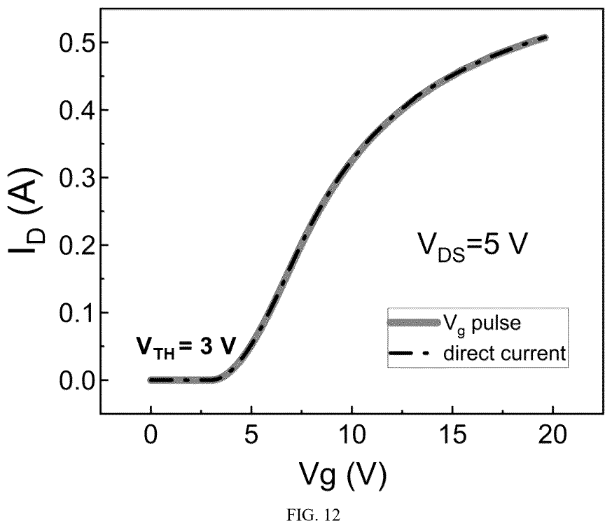

I-V test was performed on the fabricated MIS gate FET. The rest results are as shown in FIG. 12, indicating that the breakdown voltage of the gate electrode reaches 22 V, the threshold voltage of the gate electrode reaches 3.1 V, and the dynamic threshold voltage drift of the gate electrode is 0.2 V. Related data are significantly increased compared with those of the traditional p-GaN E-HEMT, proving that the present application has good advantages in the aspects of gate control performance and its reliability.

### Example 2

A fabricating method of a group III nitride enhanced FET comprised the following steps:
1) A depleted HEMT (D-HEMT) epitaxial wafer was grown in a substrate.

Specifically, a 600 nm AlN/AlGaN transition layer, a 4 μm C-doped Al_{0.07}Ga_{0.93}N high-resistance layer, an 300 nm high-quality low-electron-concentration unintentionally doped GaN layer and a 45 nm Al_{0.18}Ga_{0.82}N barrier layer were successively deposited on a Si<111> substrate by using an MOCVD method to form a depleted HEMT epitaxial wafer of aAlGaN/GaN heterojunction with a two-dimensional electronic gas square resistance of 3602/0, a concentration of about 9.8×10¹² cm⁻³ and a mobility of about 1800cm²V⁻¹s⁻¹.
2) A gate groove was processed in a gate region of the depleted HEMT epitaxial wafer.

Specifically, the gate region of the depleted HEMT epitaxial wafer was patterned by using photoresist as a mask, and placed in ICP etching equipment to etch off all the Al_{0.18}Ga_{0.82}N barrier layer and the about 8 nm unintentionally doped GaN layer in the gate region at a low speed, so as to form the gate groove;
the photoresist was removed by using an organic washing method such as acetone, and the depth of the gate groove was measured as 47-48 nm via test;
after residual organic matters were removed by using a piranha solution, the depleted HEMT epitaxial wafer with the grate groove was placed in tetramethylammonium hydroxide to be heated for a certain time, then transferred to a hydrofluoric acid BOE to be soaked to remove surface oxides and surface silicon impurities.
3) An MIS gate structure, a source electrode and a drain electrode were fabricated on the depleted HEMT epitaxial wafer.

Specifically, the treated depleted HEMT epitaxial wafer was re-loaded into the MOCVD equipment, heated to 900° C. along the temperature of a furnace and the temperature was maintained for a while, then a Ga source, NH₃, N₂, Cp₂Mg and the like were introduced into the furnace, so as to perform epitaxial growth on the surface of the depleted HEMT epitaxial wafer to successively form an about 10 nm p-GaN layer A and an about 5 nm p-Al_{0.15}Ga_{0.85}N layer, the concentration of Mg in the p-GaN layer and the p-Al_{0.15}Ga_{0.85}N layer was gradually increased from 5×10¹⁷ cm⁻³ to 1×10¹⁹ cm⁻³ along the direction deviating from the depleted HEMT epitaxial wafer.

After epitaxy was performed on the p-GaN layer and the p-Al_{0.15}Ga_{0.85}N layer, the atmosphere in the MOCVD furnace was switched to N₂, the temperature of the MOCVD furnace was maintained at 800° C. for a while followed by cooling to room temperature;
the depleted HEMT epitaxial wafer was taken and placed in ALD equipment for deposition to form a 20 nm Al₂O₃ layer on the p-Al_{0.15}Ga_{0.85}N layer;
the source region and the drain region were photoetched and patterned and then placed in the ICP equipment to etch off the Al₂O₃ layer, the p-GaN layer, the p-Al_{0.15}Ga_{0.85}N layer and the Al_{0.18}Ga_{0.82}N layer which were located in the source region and the drain region, a layer of Ti/Al/Ti/Au=20/130/50/150 nm stack metal was deposited in the source region and the drain region, followed by rapidly annealing for 30 s at the atmosphere of N₂ at the temperature of 890° C. to fabricate the source electrode and the drain electrode which were in ohmic contact;
a layer of Ti/Au=20/200 nm stack metal was deposited in the gate region followed by rapidly annealing for 60 s at the atmosphere of N₂ and at the temperature of 500° C. so as to form an MIS gate structure, thereby fabricating the MIS gate FET, as shown in FIG. 8.

I-V test was performed on the fabricated GaN MOS gate FET. The rest results are as shown in FIG. 12, indicating that the breakdown voltage of the GaN MOS gate FET reaches 25 V, the threshold voltage of the GaN MOS gate FET reaches 2.8 V, and the dynamic threshold voltage drift of the GaN MOS gate FET reaches 0.08 V. Related data are significantly increased compared with those of the traditional p-GaN E-HEMT, proving that the present application has good advantages in the aspects of gate control performance and its reliability.

It should be understood that the above examples are only for illustrating the technical concept and features of the present application for the purpose of allowing persons familiar with this technology to know the contents of the present application and implement the present application, but cannot limit the scope of protection of the present application. Equivalent changes or modifications made according to the spirit of the present application shall be included within the scope of protection of the present application.

What is claimed is:

1. An enhanced field effect transistor, comprising an epitaxial structure, a metal-insulator-semiconductor/metal-oxide-semiconductor (MIS/MOS) gate structure, a source electrode, and a drain electrode,
wherein the epitaxial structure comprises at least one heterojunction, the at least one heterojunction comprises a first semiconductor layer and a second semiconductor layer stacked along a predetermined direction, a carrier channel is formed in an interface between the first semiconductor layer and the second semiconductor layer, and the source electrode and the drain electrode are arranged in an ohmic region of the epitaxial structure and electrically connected with the carrier channel; a gate region of the epitaxial structure is provided with a gate groove, a groove bottom of the gate groove is located in the first semiconductor layer, a notch is located in the second semiconductor layer, and the carrier channel is separated by the gate groove; and
the MIS/MOS gate structure comprises a third semiconductor layer, a gate dielectric layer, and a gate electrode successively stacked along a predetermined direction, the third semiconductor layer is at least arranged in the gate groove, the MIS/MOS gate structure has a field effect on a regulation of the carrier channel, electrons are reversely generated in the third semiconductor layer when a forward voltage is applied to the gate electrode, and the carrier channel located at each of two sides of the gate electrode are electrically connected via the electrons.

2. The enhanced field effect transistor according to claim 1, wherein the third semiconductor layer comprises at least one p-type semiconductor layer and/or at least one unintentionally doped semiconductor layer with acceptor or acceptor-like defects; and
a thickness of the third semiconductor layer is 15-16 nm.

3. The enhanced field effect transistor according to claim 2, wherein the at least one p-type semiconductor layer is Mg-doped, and a Mg doping concentration of the at least one p-type semiconductor layer is less than 1×10²⁰ cm⁻³;
an Mg element in the at least one p-type semiconductor layer is uniformly, linearly or gradually distributed; and
a material of the at least one p-type semiconductor layer comprises a p-type group III nitride.

4. The enhanced field effect transistor according to claim 2, wherein a the concentration of the acceptor or acceptor-like defects of the at least one_unintentionally doped semiconductor layer is more than 1×10¹⁵ cm⁻³, the at least one_unintentionally doped semiconductor layer is in a high-resistivity state; and
a material of the at least one unintentionally doped semiconductor layer comprises an unintentionally Mg-doped group III nitride.

5. The enhanced field effect transistor according to claim 1, wherein the third semiconductor layer is arranged in the gate region of the epitaxial structure, or between the gate region and the ohmic region;
and/or the gate dielectric layer is arranged in the gate region of the epitaxial structure and the region between the gate region and the ohmic region;
a material of the gate dielectric layer comprises Al₂O₃, HfO₂, Si₃N₄, or SiO₂;
a thickness of the gate dielectric layer is 5-100 nm;
and/or the epitaxial structure comprises two or more of the at least one heterojunction stacked along a predetermined direction, and the groove bottom of the gate groove is located in the first semiconductor layer of the at least one heterojunction at a bottom;
materials of the first semiconductor layer and the second semiconductor layer both comprise group III nitrides;
and/or the epitaxial structure further comprises a high-resistance voltage-tolerance layer and a transition layer, the at least one heterojunction is arranged on the high-resistance voltage-tolerance layer along the predetermined direction, and the high-resistance voltage-tolerance layer is arranged on the transition layer; and
materials of the high-resistance voltage-tolerance layer and the transition layer both comprise group III nitrides.

6. A fabricating method of an enhanced field effect transistor, comprising:
providing an epitaxial structure, wherein the epitaxial structure comprises at least one heterojunction comprising a first semiconductor layer and a second semiconductor layer stacked along a predetermined direction, and a carrier channel is formed at an interface between the first semiconductor layer and the second semiconductor layer;
removing the second semiconductor layer and a part of the first semiconductor layer located in a gate region of the epitaxial structure, wherein a gate groove is formed, and the carrier channel is separated by the gate groove;
forming a third semiconductor layer, a gate dielectric layer, and a gate electrode successively stacked at least in the gate region of the epitaxial structure, wherein an MIS/MOS gate structure is formed, wherein the MIS/MOS gate structure has a field effect on a the regulation of the carrier channel, electrons are reversely generated in the third semiconductor layer when a forward voltage is applied to the gate electrode, and the carrier channel located at each of two sides of the gate groove is electrically connected via the electrons; and
forming a source electrode and a drain electrode in an ohmic region of the epitaxial structure, wherein the source electrode and the drain region are electrically connected with the carrier channel.

7. The fabricating method according to claim 6, wherein the third semiconductor layer comprises at least one p-type semiconductor layer and/or at least one unintentionally doped semiconductor layer with acceptor or acceptor-like defects; and
a thickness of the third semiconductor layer is 15-16 nm.

8. The fabricating method according to claim 7, wherein the at least one p-type semiconductor layer is Mg-doped, and a Mg doping concentration of the at least one p-type semiconductor layer is less than 1×10²⁰ cm⁻³; and
a material of the at least one p-type semiconductor layer comprises a p-type group III nitride, wherein
the p-type group III nitride comprises p-GaN, p-AlGaN, p-AlInGaN, p-InGaN, p-AlInN, or p-(Al,In)GaN.

9. The fabricating method according to claim 7, wherein a concentration of the acceptor or acceptor-like defects of the at least one unintentionally doped semiconductor layer is 1×10¹⁵ cm⁻³ or above, and the at least one unintentionally doped semiconductor layer is in a high-resistivity state; and
a material of the at least one unintentionally doped semiconductor layer comprises an unintentionally Mg-doped group III nitride, wherein
the unintentionally Mg-doped group III nitride comprises unintentionally Mg-doped GaN, AlGaN, AlInGaN, InGaN, AlInN, or (Al,In)GaN.

10. The fabricating method according to claim 7, wherein the third semiconductor layer is arranged in the gate region of the epitaxial structure, or the third semiconductor layer is arranged in the gate region of the epitaxial structure and a region between the gate region and the ohmic region;
and/or the gate dielectric layer is arranged in the gate region of the epitaxial structure and the region between the gate region and the ohmic region;
a material of the gate dielectric layer comprises Al₂O₃, HfO₂, Si₃N₄, or SiO₂;
a thickness of the gate dielectric layer is 5-100 nm;
and/or the epitaxial structure comprises two or more of the at least one heterojunction stacked along a predetermined direction, and a groove bottom of the gate groove is located in the first semiconductor layer of the at least one heterojunction at a bottom; and
materials of the first semiconductor layer and the second semiconductor layer both comprise group III nitrides, wherein
the group III nitrides comprise GaN, AlGaN, AlInGaN, InGaN, AlInN, or (Al,In)GaN.

11. The enhanced field effect transistor according to claim 2, wherein materials of the at least two p-type semiconductor layers or the at least two unintentionally doped semiconductor layers with the acceptor or acceptor-like defects are different.

12. The enhanced field effect transistor according to claim 3, wherein the Mg doping concentration of the at least one p-type semiconductor layer is 1×10¹⁵ cm⁻³-1×10²⁰ cm⁻³.

13. The enhanced field effect transistor according to claim 3, wherein the Mg doping concentration of the at least one p-type semiconductor layer is 5×10¹⁷ cm⁻³-1×10¹⁹ cm⁻³.

14. The enhanced field effect transistor according to claim 3, wherein the material of the at least one p-type semiconductor layer comprises p-GaN, p-AlGaN, p-AlInGaN, p-InGaN, p-AlInN, or p-(Al,In)GaN.

15. The enhanced field effect transistor according to claim 4, wherein the concentration of the acceptor or acceptor-like defects of the at least one unintentionally doped semiconductor layer is 1×10¹⁵ cm⁻³-1×10²⁰ cm⁻³.

16. The enhanced field effect transistor according to claim 4, wherein the concentration of the acceptor or acceptor-like defects of the at least one unintentionally doped semiconductor layer is 5×10¹⁷ cm⁻³-1×10¹⁹ cm⁻³.

17. The enhanced field effect transistor according to claim 4, wherein the material of the at least one unintentionally doped semiconductor layer comprises unintentionally Mg-doped GaN, AlGaN, AlInGaN, InGaN, AlInN, or (Al,In)GaN.

18. The enhanced field effect transistor according to claim 5, wherein the materials of the first semiconductor layer and the second semiconductor layer comprise GaN, AlGaN, AlInGaN, InGaN, AlInN, or (Al,In)GaN.

19. The fabricating method according to claim 7, wherein materials of the at least two p-type semiconductor layers or the at least two unintentionally doped semiconductor layers with the acceptor or acceptor-like defects are different.

20. The fabricating method according to claim 8, wherein the Mg doping concentration of the at least one p-type semiconductor layer is 1×10¹⁵ cm⁻³-1×10²⁰ cm⁻³ or 5×10¹⁷ cm⁻³-1×10¹⁹ cm⁻³.
